(19) United States
(12) Patent Application Publication
(10) Pub. No.: US 2009/0252591 A1
(43) Pub. Date: Oct. 8, 2009

(54) IN-LINE APPARATUS

(76) Inventor: Nak-Do JUNG, Cheonan-si (KR)

Correspondence Address: F. CHAU & ASSOCIATES, LLC, 130 WOODBURY ROAD, WOODBURY, NY, 11797, US

(21) Appl. No.: 12/416,316

(22) Filed: Apr. 1, 2009

(30) Foreign Application Priority Data
Apr. 3, 2008 (KR) 10-2008-0031200

(51) Int. Cl. B65H 1/00; C23C 14/34

(52) U.S. Cl. 414/805; 204/298.25

(57) ABSTRACT

An in-line apparatus includes a loader chamber loading and unloading a substrate, a plurality of process chambers coupled in series to the loader chamber, and respectively and sequentially performing predetermined processes for the substrate, and at least one buffer chamber disposed in parallel to the process chambers, wherein the buffer chamber replaces at least one process chamber to transfer the substrate therethrough.

### CROSS-REFERENCE TO RELATED APPLICATION

This application claims priority to Korean Patent Application No. 10-2008-0031200 filed on Apr. 3, 2008, the entire contents of which are incorporated herein by reference.

### BACKGROUND OF THE INVENTION

(a) Technical Field

The present disclosure relates to an in-line apparatus, and more particularly, to an in-line apparatus for manufacturing electrical wiring or an electrode used for a micro-electronic device.

(b) Discussion of the Related Art

A micro-electronic device such as a display device or a semiconductor device includes electrical wiring or electrodes. For example, flat panel displays such as a liquid crystal display, an organic light emitting device, and a plasma display device include electrodes made of indium tin oxide (ITO), indium zinc oxide (IZO), or a metal, and a plurality of signal lines.

The signal lines or the electrodes may have a single-layered structure or a multi-layered structure, and can be formed by a sputtering method. In the sputtering method, gas ions having high energy of plasma formed in a vacuum chamber collide with a target, and then atoms ejected from the target due to the collision are deposited as a thin film on a substrate.

Devices for forming the signal lines and the electrodes can be divided into a cluster type and an in-line type according to, for example, configuration and/or a transfer method. In the in-line type, process chambers are disposed in series such that continuous transfer of substrates is possible. Accordingly, if the in-line type is used when forming signal lines and electrodes, process speed may be increased. However, in the in-line apparatus, when the target is exhausted and exchanged in one chamber, or when defects are generated and preventive maintenance is performed, the entire operation of the in-line apparatus stops.

### SUMMARY OF THE INVENTION

Accordingly, exemplary embodiments of the present invention provide an in-line apparatus that can be operated during preventive maintenance of a portion of the chambers thereof.

According to an exemplary embodiment of the present invention, an in-line apparatus comprises a loader chamber loading and unloading a substrate, a plurality of process chambers coupled in series to the loader chamber, and respectively and sequentially performing predetermined processes for the substrate, and at least one buffer chamber disposed in parallel to the process chambers, wherein the buffer chamber replaces at least one process chamber to transfer the substrate therethrough.

The in-line apparatus may further include at least one rail, and the buffer chamber and the process chambers can be disposed on the rail and move along the rail.

The process chambers ma include a first process chamber and a second process chamber connected thereto, and the first process chamber and the second process chamber can disposed on different rails.

The buffer chamber can be positioned on a rail where the second process chamber is disposed.

When the second process chamber is separated from the first process chamber and moves away from the first process chamber, the buffer chamber may moves to be coupled in series to the first process chamber.

The in-line apparatus may further comprise a transfer chamber connected to one of the process chambers, wherein the transfer chamber includes a direction-converting apparatus to transfer the substrate back to the loader chamber.

The in-line apparatus may further comprise a heater chamber disposed in series between the loader chamber and one of the process chambers.

The process chambers may execute a sputtering process.

The process chambers may include first and fourth process chambers having a molybdenum target, and second and third process chambers disposed between the first process chamber and the fourth process chamber and, respectively having an aluminum target, and the first to fourth process chambers can be disposed on different rails, and the at least one buffer chamber may include a first buffer chamber positioned on a rail where the second process chamber is disposed, and a second buffer chamber positioned on a rail where the third process chamber is disposed.

The process chambers and the at least one buffer chamber can be in a vacuum state.

When the second process chamber is separated from the first and third process chambers and moves away from the first and third process chambers, the first buffer chamber can move between the first and third process chambers to be coupled in series to the first and third process chambers and provide a transfer space in a vacuum state.

When the third process chamber is separated from the second and fourth process chambers and moves away from the second and fourth process chambers, the second buffer chamber can move between the second and fourth process chambers to be coupled in series to the second and fourth process chambers and provide a transfer space in the vacuum state.

The process chambers ma include first and second process chambers having an ITO or IZO target, and the first process chamber and the second process chamber can be disposed on different rails, and the buffer chamber can be disposed on a rail where the first process chamber is disposed.

When the first process chamber is separated from the second process chamber and moves away from the second process chamber, the buffer chamber can move to be connected to the second process chamber and provide a transfer space in the vacuum state.

According to an exemplary embodiment of the present invention, an apparatus for manufacturing electrical wiring or an electrode used for a micro-electronic device, the apparatus comprises a loader chamber loading a substrate, a first process chamber receiving the substrate from the loader chamber, a second process chamber connected to the first process chamber, a third process chamber connected to the second process chamber, a fourth process chamber connected to the third process chamber, and a first buffer chamber connected to the second process chamber, wherein the first buffer chamber replaces the second process chamber to transfer the substrate from the first process chamber to the third process chamber.

The apparatus may further comprise a second buffer chamber connected to the third process chamber, wherein the second buffer chamber can replace the third process chamber to transfer the substrate from the second process chamber to the fourth process chamber therethrough.

A loadlock chamber and a heater chamber can be formed between the loader chamber and the first process chamber.

The fourth process chamber may include elements for changing a transfer direction of the substrate.

According to an exemplary embodiment of the present invention, a method of transferring a substrate between chambers comprises loading a substrate in a loader chamber, transferring the substrate from the loader chamber to a first process chamber connected to the loader chamber, transferring the substrate from the first process chamber to a second process chamber connected to the first process chamber, transferring the substrate from the second process chamber to a third process chamber connected to the second process chamber, and replacing the second process chamber with a first buffer chamber to transfer the substrate from the first process chamber to the third process chamber through the buffer chamber in a vacuum state when the second process chamber is separated from the first and third process chambers. According to an exemplary embodiment of the present invention, the apparatus operation is not stopped during the preventive maintenance of a portion of the chambers. Accordingly, productivity of the products may be increased.

### BRIEF DESCRIPTION OF THE DRAWINGS

Exemplary embodiments of the present invention can be understood in more detail from the following descriptions taken in conjunction with the accompanying drawings in which:

FIG. 1 is a top plan view of an in-line apparatus according to an exemplary embodiment of the present invention;

FIG. 2 is a cross-sectional view of a process chamber according to an exemplary embodiment of the present invention; and

FIG. 3 is a top plan view showing an operation of an in-line apparatus according to an exemplary embodiment of the present invention.

### DETAILED DESCRIPTION OF EXEMPLARY EMBODIMENTS

The invention is described more fully hereinafter with reference to the accompanying drawings, in which exemplary embodiments of the invention are shown. This invention may, however, be embodied in many different forms and should not be construed as limited to the embodiments set forth herein. It will be understood that when an element such as a layer, film, region, or substrate is referred to as being “on” another element, it can be directly on the other element or intervening elements may also be present.

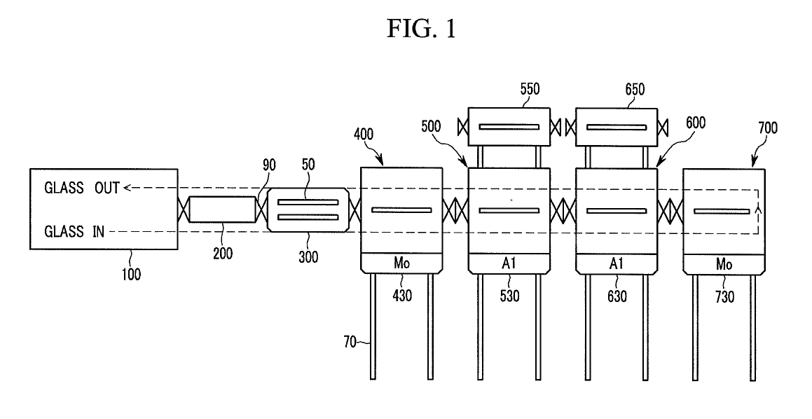

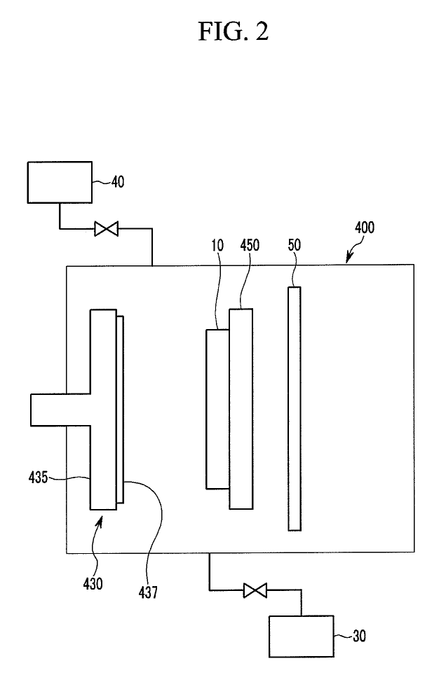

An in-line apparatus according to an exemplary embodiment of the present invention is described with reference to FIG. 1 and FIG. 2.

FIG. 1 is a top plan view of an in-line apparatus according to an exemplary embodiment of the present invention. FIG. 2 is a cross-sectional view of a process chamber according to an exemplary embodiment of the present invention.

Referring to FIG. 1 and FIG. 2, the in-line apparatus includes a loader chamber 100, a loadlock chamber 200, a heater chamber 300, and first to fourth process chambers 400, 500, 600, and 700. The chambers 100, 200, 300, 400, 500, 600, and 700 are coupled in series through valves 90 interposed therebetween, and execute a series of processes for a substrate 10.

The loader chamber 100 executes pre-aligning of the substrate 10 and loading of the substrate 10. In the loader chamber 100, the substrate 10 is unloaded after predetermined processes are completed.

The loadlock chamber 200 can be connected to the loader chamber 100 through the valve 90 interposed therebetween, and receives the substrate 10 from the loader chamber 100 under an atmospheric pressure state. The substrate 10 can be transferred in a vertically standing state. Next, the loadlock chamber 200 is changed from the atmospheric pressure state to a vacuum state.

The heater chamber 300 can be connected to the loadlock chamber 200 through the valve 90 interposed therebetween, and receives the substrate 10 from the loadlock chamber 200 under the vacuum state. The transmitted substrate 10 is heated by a heater 50 to an appropriate temperature.

In the first to fourth process chambers 400, 500, 600, and 700, signal lines or electrodes are formed on the substrate 10 that is transmitted from the heater chamber 300 through, for example, a sputtering method. The process chambers 400, 500, 600, and 700 are coupled in series to each other, and respectively include material supply units 430, 530, 630, and 730 and a heater 50 to maintain the temperature of the substrate 10. Each of the first to fourth process chambers 400, 500, 600, and 700 may include a substrate supporter 450, a gas supply unit 40, a vacuum pump 30, and a radio frequency induction file (not shown). The signal lines and the electrodes may be formed by different methods other than the sputtering method.

The material supply units 430, 530, 630, and 730 are, respectively, connected to a surface of the process chambers 400, 500, 600, and 700. Each of the material supply units 430, 530, 630, and 730 includes a target 437 that is a material to be attached to the substrate 10 and a cathode 435 connected to the target 437. The target 437 may be separated from the process chamber 400 for exchange of the target 437.

The target 437 may comprise, for example, an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, nitrides, chromium (Cr), tantalum (Ta), or titanium (Ti). In an exemplary embodiment, the first and fourth material supply units 430 and 730 include a molybdenum target, and the second and third material supply units 530 and 630 include an aluminum target.

The process chambers 400, 500, 600, and 700 with the material supply units 430, 530, 630, and 730 are disposed on rails 70, and may move along the rails 70.

Buffer chambers 550 and 650 are disposed on the rails 70 on which the second and third process chambers 500 and 600 are disposed. The buffer chambers 550 and 650 are apart from the second and third process chambers 500 and 600. The buffer chambers 550 and 650 provide a space, for example, a vacuum state space, where the substrate 10 may be transferred during a preventive maintenance process of the second process chamber 500 or the third process chamber 600. The buffer chambers 550 and 650 may be moved along the rails 70.

The fourth process chamber 700 includes a direction-converting apparatus for changing the transfer direction of the substrate 10 back to the loader chamber 100 after having completed a predetermined process. The fourth process chamber 700 may be a transfer chamber having the direction-converting apparatus. In the transfer chamber, a process of forming a thin film may or may not be performed.

The operation of the process chambers 400, 500, 600, and 700 is described with reference to FIG. 2. In FIG. 2, the first process chamber 400 is shown. The second to fourth process chambers 500, 600, and 700 have substantially the same structure and operation as the first process chamber 400. In an exemplary embodiment, the fourth process chamber 700 further includes elements for converting the transfer direction of the substrate 10 and elements for the sputtering process.

The first process chamber 400 includes the material supply unit 430 having the cathode 435 and the target 437, the supporter 450 supporting the substrate 10, the heater 50, the vacuum pump 30, and the gas supply unit 40. The substrate supporter 450 may function as an anode.

For forming a layer on the substrate 10, the substrate 10 is loaded in the process chamber 400 while maintaining the vacuum state through the vacuum pump 30. Next, an inert gas such as argon gas is injected into the process chamber 400 through the gas supply unit 40. Then, the cathode 435 and the substrate supporter 450 are supplied with a radio frequency (RF) or a direct current (DC) to generate plasma. Thus, argon ions (Ar⁺) generated in the plasma collide with the target 437, and atoms of the target 437 exit the target 437 and are attached to the substrate 10 to form a thin film.

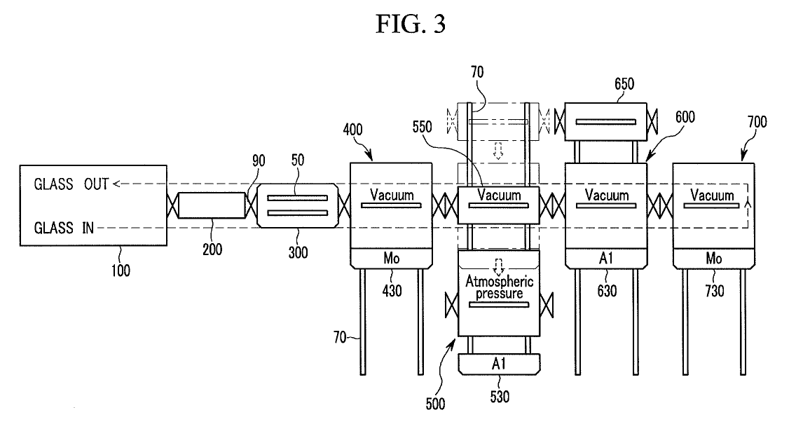

An operation of the in-line apparatus according to an exemplary embodiment of the present invention is described with reference to FIG. 2 and FIG. 3.

FIG. 3 is a top plan view showing an operation of an in-line apparatus according to an exemplary embodiment of the present invention.

Referring to FIG. 2 and FIG. 3, the substrate 10 is loaded in the loader chamber 100 under atmospheric pressure, and is transferred to the loadlock chamber 200. Next, the loadlock chamber 200 is changed to the vacuum state, and the substrate 10 is transferred to the heater chamber 300. The substrate 10 is heated to an appropriate temperature by the heater 50 disposed in the heater chamber 300. The heated substrate 10 is then transferred to the process chambers 400, 500, 600, and 700. The process chambers 400, 500, 600, and 700 are maintained in the vacuum state.

In the process chambers 400, 500, 600, and 700, a pixel electrode, a common electrode, a signal line, and/or a drain electrode can be formed by, for example, the sputtering method. The signal line can be a gate line having a gate electrode or a data line having a source electrode.

The gate line may comprise, for example, an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). However, the signal line may have a multi-layered structure including two conductive layers having different physical properties. One of the conductive layers may be formed using a metal having low resistivity, such as an aluminum-based metal or a copper-based metal, to reduce signal delay or voltage drop. In an exemplary embodiment, other conductive layers may be formed using a material having good physical, chemical, and electrical contact characteristics with indium tin oxide (ITO) and indium zinc oxide (IZO). Examples of the other conductive layers can be a molybdenum-based metal, chromium, tantalum, or titanium. Examples of the combination for the two layer structure may include a lower chromium film and an upper aluminum (alloy) film, or a lower aluminum (alloy) film and an upper molybdenum (alloy) film.

The data line and the drain electrode may be formed using a refractory metal such as, for example, molybdenum, chromium, tantalum, titanium, or an alloy thereof, and may have a multi-film structure including a refractory metal film and a low resistance conductive layer. Examples of the multi-film structure may include a dual film of a lower chromium or molybdenum film and an upper aluminum (alloy) film, or a triple film of a lower molybdenum (alloy) film, an intermediate aluminum (alloy) film, and an upper molybdenum (alloy) film. In an exemplary embodiment, the data line and the drain electrode may be formed using various metals or conductors other than the above-mentioned materials.

The pixel electrode or the common electrode may comprise, for example, a transparent conductive material such as ITO or IZO, or a reflective metal such as aluminum, silver, chromium, or alloys thereof.

In an exemplary embodiment, the process chambers 400, 500, 600, and 700 are used for forming a triple film of a lower molybdenum film, an intermediate aluminum film, and an upper molybdenum film.

The lower molybdenum layer is formed in the first process chamber 400, the intermediate aluminum layer is formed in the second and third process chambers 500 and 600, and the upper molybdenum layer is formed in the fourth process chamber 700. If the target material to be attached to the substrate 10 is exhausted, the process of forming a layer is stopped. The material supply unit 430 with an exhausted target is separated from the process chamber 400 to exchange the target. The exhaustion degree is different according to the kind of target during the same time frame. For example, the exhausted amount of the molybdenum target is less than that of the aluminum target for a certain period. Accordingly, in an exemplary embodiment, there are two process chambers 500 and 600 having the aluminum target with the faster exhaustion speed. When a target is exhausted, the material supply units 530, 630 or 730 are separated from the process chambers 500, 600 or 700, respectively, to replace the targets in the material supply units 530, 630 or 730.

In the first process chamber 400, the molybdenum lower layer is formed on the substrate 10 that is transferred from the heater chamber 300. The substrate 10 on which the molybdenum lower layer is formed is transferred to the second process chamber 500. In the second process chamber 500, the intermediate aluminum layer is formed on the substrate 10. The substrate 10 having the intermediate aluminum layer is then transferred to the fourth process chamber 700 through the third process chamber 600. The third process chamber 600 provides a transfer space in the vacuum state for the substrate 10 transferring from the second process chamber 500 to the fourth process chamber 700. A sputtering process is not executed in the third process chamber 600. In the fourth process chamber 700, the upper molybdenum layer is formed on the substrate 10, and the substrate 10 of which the process is completed is transferred back to the loader chamber 100 through the path that the substrate 100 has passed. In the in-line apparatus according to an exemplary embodiment of the present invention, the substrate 10 moves in a first direction, and then moves in a second direction which is opposite to the first direction. A system in which the loading and unloading are both executed in the loader chamber 100 without an additional unloader chamber is referred to as an interback system.

The aluminum target is exhausted faster than the molybdenum target such that the aluminum target used in the second process chamber 500 is exchanged more often than the molybdenum target in different process chambers. Accordingly, if the aluminum target of the second material supply unit 530 is exhausted, a process of forming a layer is temporary stopped, and the second process chamber 500 is separated from the first and third process chamber 400 and 600 and moved downwardly along the rail 70. In an exemplary embodiment, the valves 90 disposed between the second process chamber 500 and the first process chamber 400, and between the second process chamber 500 and the third process chamber 600, are locked such that the first and third process chambers 400 and 600 may be maintained in the vacuum state. When the second process chamber 500 is moved, the buffer chamber 550 is moved downwardly. Next, the buffer chamber 550 is coupled in series with the first and third process chambers 400 and 600 through the valves 90, and provides a space through which the substrate 10 may be transferred in the vacuum state. This period is referred to as a mode change period, and takes about 1 hour in an exemplary embodiment of the present invention.

When changing the target of the second material supply unit 530, the buffer chamber 550 provides the transfer space in the vacuum state instead of the second process chamber 500 such that the process is not stopped except for the mode change period. The target of the second material supply unit 530 is exchanged in a state in which the second material supply unit 530 is separated from the second process chamber 500. However, the target may be exchanged in a state where the second material supply unit 530 is not separated from the second process chamber 500. In an exemplary embodiment, the target exchange is executed under atmospheric pressure and the exchange time is about 12 hours.

When the buffer chamber 550 is coupled in series between the first and third process chambers 400 and 600, the process that was stopped during the mode change period begins. The substrate 10 from the first process chamber 400 passes through the buffer chamber 550 and is transferred to the third process chamber 600, and the intermediate layer is formed on the substrate 10. Next, the substrate 10 is transferred to the fourth process chamber 700, and the upper molybdenum layer is formed on the substrate 10.

If the aluminum target of the third material supply unit 630 is exhausted, the mode is converted. That is, the sputtering process is temporary stopped, the third process chamber 600 and the buffer chamber 650 move downwardly along the rail 70, and the second process chamber 500 and the buffer chamber 550 move upwardly. Thus, the first process chamber 400 and the second process chamber 500 are connected to each other through the valve 90, and the buffer chamber 650 is connected between the second process chamber 500 and the fourth process chamber 700. In an exemplary embodiment, the process for forming the intermediate aluminum layer is executed in the second process chamber 500, and the buffer chamber 650 provides the transfer space of the vacuum state.

Accordingly, in exemplary embodiments of the present invention, the process is stopped only during the mode change period. Furthermore, maintenance of the second and third process chambers 500 and 600 can be performed during the exchange of the target 437.

Although exemplary embodiments of the present invention have been described herein with reference to the accompanying drawings, it is to be understood that the present invention should not be limited thereto and that various other changes and modifications may be affected therein by one of ordinary skill in the related art without departing from the scope or spirit of the invention. All such changes and modifications are intended to be included within the scope of the invention.

What is claimed is:

1. An in-line apparatus comprising:
a loader chamber loading and unloading a substrate;
a plurality of process chambers coupled in series to the loader chamber, and respectively and sequentially performing predetermined processes for the substrate; and
at least one buffer chamber disposed in parallel to the process chambers,
wherein the buffer chamber replaces at least one process chamber to transfer the substrate therethrough.

2. The in-line apparatus of claim 1, wherein:
the in-line apparatus further includes at least one rail; and
the buffer chamber and the process chambers are disposed on the rail and move along the rail.

3. The in-line apparatus of claim 2, wherein:
the process chambers include a first process chamber and a second process chamber connected thereto;
the first process chamber and the second process chamber are disposed on different rails; and
the buffer chamber is positioned on a rail where the second process chamber is disposed.

4. The in-line apparatus of claim 3, wherein,
when the second process chamber is separated from the first process chamber and moves away from the first process chamber, the buffer chamber moves to be coupled in series to the first process chamber.

5. The in-line apparatus of claim 2, further comprising
a transfer chamber connected to one of the process chambers,
wherein the transfer chamber includes a direction-converting apparatus to transfer the substrate back to the loader chamber.

6. The in-line apparatus of claim 5, further comprising
a heater chamber disposed in series between the loader chamber and one of the process chambers.

7. The in-line apparatus of claim 2, wherein the process chambers execute a sputtering process.

8. The in-line apparatus of claim 7, wherein:
the process chambers include first and fourth process chambers having a molybdenum target, and second and third process chambers disposed between the first process chamber and the fourth process chamber and, respectively having an aluminum target;
the first to fourth process chambers are disposed on different rails; and
the at least one buffer chamber includes a first buffer chamber positioned on a rail where the second process chamber is disposed, and a second buffer chamber positioned on a rail where the third process chamber is disposed.

9. The in-line apparatus of claim 8, wherein the process chambers and the at least one buffer chamber are in a vacuum state.

10. The in-line apparatus of claim 9, wherein:
when the second process chamber is separated from the first and third process chambers and moves away from the first and third process chambers, the first buffer chamber moves between the first and third process chambers to be coupled in series to the first and third process chambers and provide a transfer space in a vacuum state.

11. The in-line apparatus of claim 10, wherein when the third process chamber is separated from the second and fourth process chambers and moves away from the second and fourth process chambers, the second buffer chamber moves between the second and fourth process chambers to be coupled in series to the second and fourth process chambers and provide a transfer space in the vacuum state.

12. The in-line apparatus of claim 7, wherein:
the process chambers include first and second process chambers having an ITO or IZO target;
the first process chamber and the second process chamber are disposed on different rails; and
the buffer chamber is disposed on a rail where the first process chamber is disposed.

13. The in-line apparatus of claim 12, wherein,
when the first process chamber is separated from the second process chamber and moves away from the second process chamber, the buffer chamber moves to be connected to the second process chamber and provide a transfer space in the vacuum state.

14. An apparatus for manufacturing electrical wiring or an electrode used for a micro-electronic device, the apparatus comprising:
a loader chamber loading a substrate;
a first process chamber receiving the substrate from the loader chamber;
a second process chamber connected to the first process chamber;
a third process chamber connected to the second process chamber;
a fourth process chamber connected to the third process chamber; and
a first buffer chamber connected to the second process chamber,
wherein the first buffer chamber replaces the second process chamber to transfer the substrate from the first process chamber to the third process chamber.

15. The apparatus of claim 14, further comprising a second buffer chamber connected to the third process chamber, wherein the second buffer chamber replaces the third process chamber to transfer the substrate from the second process chamber to the fourth process chamber therethrough.

16. The apparatus of claim 14, wherein a loadlock chamber and a heater chamber are formed between the loader chamber and the first process chamber.

17. The apparatus of claim 14, wherein the fourth process chamber includes elements for changing a transfer direction of the substrate.

18. A method of transferring a substrate between chambers, the method comprising:
loading a substrate in a loader chamber;
transferring the substrate from the loader chamber to a first process chamber connected to the loader chamber;
transferring the substrate from the first process chamber to a second process chamber connected to the first process chamber;
transferring the substrate from the second process chamber to a third process chamber connected to the second process chamber; and
replacing the second process chamber with a first buffer chamber to transfer the substrate from the first process chamber to the third process chamber through the buffer chamber in a vacuum state when the second process chamber is separated from the first and third process chambers.
